(19) United States
(12) Patent Application Publication
(10) Pub. No.: US 2021/0125896 A1
(43) Pub. Date: Apr. 29, 2021

(54) FILLED LIQUID METAL THERMAL INTERFACE MATERIALS

(71) Applicant: Intel Corporation, Santa Clara, CA (US)

(72) Inventors: Kyle J. Arrington, Chandler, AZ (US); Aaron Mccann, Chandler, AZ (US); Kelly Lofgreen, Phoenix, AZ (US); Aravindha R. Antoniswamy, Phoenix, AZ (US); Shankar Devasenathipathy, Tempe, AZ (US)

(73) Assignee: Intel Corporation, Santa Clara, CA (US)

(21) Appl. No.: 16/662,562

(22) Filed: Oct. 24, 2019

(51) Int. Cl. H01L 23/373; H01L 23/532; H01L 21/48

(52) U.S. Cl. CPC H01L 23/3736; H01L 21/4882; H01L 23/53209

(57) ABSTRACT

A thermal interface material may be formed comprising a liquid metal and a corrosion resistant filler material. The thermal interface material may be used in an integrated circuit assembly between at least one integrated circuit device and a heat dissipation device, wherein the corrosion resistant filler material changes the physical properties of the thermal interface material, which may prevent failure modes from occurring during the operation of the integrated circuit assembly and may assist in maintaining a bond line thickness between the at least one integrated circuit device and the heat dissipation device.

### TECHNICAL FIELD

Embodiments of the present description generally relate to the removal of heat from integrated circuit devices, and, more particularly, to thermal management solutions using filled liquid metal thermal interface materials.

### BACKGROUND

The integrated circuit industry is continually striving to produce ever faster, smaller, and thinner integrated circuit packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. This issue becomes even more critical when multiple integrated circuit devices are incorporated into multi-device or multi-chip packages (MCPs). Thus, heat dissipation devices are used to remove heat from the integrated circuit devices in an integrated circuit package. In one example, at least one integrated circuit device may be mounted to a substrate and the heat dissipation device, known as an integrated heat spreader, may be attached to the substrate and extend over the integrated circuit device(s) to form the integrated circuit package. The distance between the integrated circuit device(s) and the heat dissipation device is known as the bond line thickness (BLT).

Generally, a thermal interface material is disposed between the integrated circuit device(s) and the heat dissipation device to form thermal contact therebetween. The thermal efficiency of the thermal interface material is critical to effectively remove heat from the integrated circuit device(s). Polymeric thermal interface materials are used extensively in integrated circuit packages. Although polymeric thermal interface materials have advantages, they also have intrinsic material properties on exposure to thereto-mechanical stresses which can result in “failure modes”. These failure modes can include voiding, which can result in delamination from the heat dissipation device and/or the integrated circuit device(s); hardening, which can lead to loss of adhesion that can also result in delamination from the heat dissipation device and/or the integrated circuit devices; and pump-out, where the thermal interface material physically moves out from between the heat dissipation device and the integrated circuit device(s). The thereto-mechanical stresses that cause failure modes result from temperature cycles during the operation of the integrated circuit package. The temperature cycles cause warpage in integrated circuit device(s) within the integrated circuit package when it heats and cools during operation. For example, in a standard integrated circuit package with one integrated circuit device, the heat dissipation device bottoms out at approximately the center of the integrated circuit device, due to the integrated circuit device's natural convex shape at room temperature. When the integrated circuit package is exposed to temperature gradients, the shape of the integrated circuit device changes from convex to flat or concave, which causes compression on the thermal interface material at edges or sidewalls of the integrated circuit device. When the integrated circuit package returns to room temperature, the integrated circuit device returns to a convex shape creating an elongation of the thermal interface material at the edge or sidewalls of the integrated circuit device. The mechanisms of compression and elongation may cause the previously discussed failure modes.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly having a heat dissipation device in thermal contact with an integrated circuit device, according to an embodiment of the present description.

FIG. 2 is close-up side cross-sectional view of the integrated circuit assembly of FIG. 1 illustrating a thermal interface material between the heat dissipation device and the integrated circuit device, according to one embodiment of the present description.

FIG. 3 is a side cross-sectional view of an integrated circuit assembly having the heat dissipation device of FIG. 1 in thermal contact with a plurality of integrated circuit devices, according to another embodiment of the present description.

FIG. 4 is a side cross-sectional view of inset 4 of the integrated circuit assembly of FIG. 3, according to one embodiment of the present description.

FIG. 5 is a side cross-sectional view of an integrated circuit assembly having a heat dissipation device in thermal contact with an integrated circuit device, according to another embodiment of the present description.

FIG. 6 is a side cross-sectional view of an integrated circuit assembly having the heat dissipation device of FIG. 5 in thermal contact with a plurality of integrated circuit devices, according to an embodiment of the present description.

FIG. 7 is a flow diagram of a method for fabricating an integrated circuit assembly, according to an embodiment of the present description.

FIG. 8 is an electronic device/system, according to an embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also se as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include a thermal interface material that comprises a liquid metal and a corrosion resistant filler material. The thermal interface material may be used in an integrated circuit assembly between at least one integrated circuit device and a heat dissipation device, wherein the corrosion resistant filler material changes the physical properties of the thermal interface material, which may prevent failure modes from occurring during the operation of the integrated circuit assembly and may assist in maintaining a bond line thickness between the at least one integrated circuit device and the heat dissipation device.

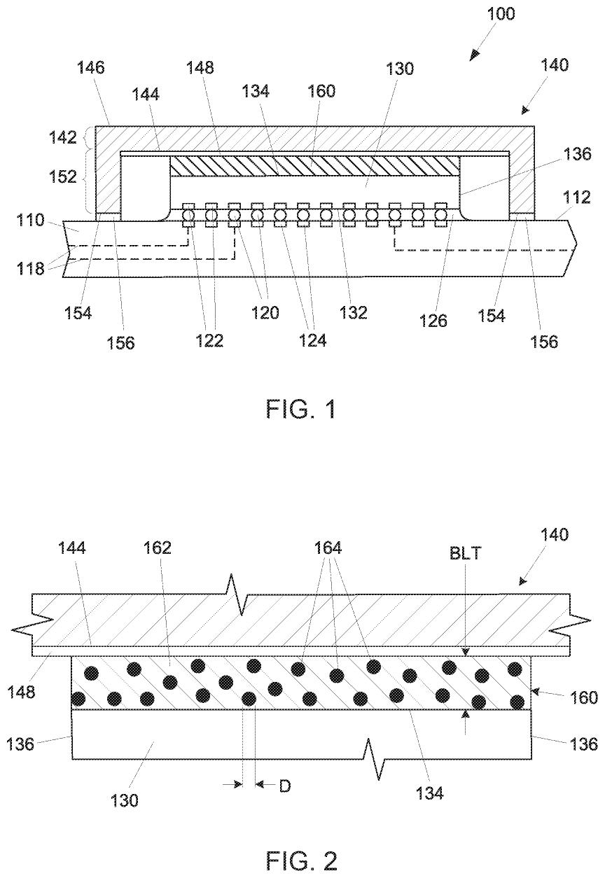

As shown in FIG. 1, an integrated circuit assembly 100 may be formed by first providing or forming an electronic substrate 110, such as an interposer, a printed circuit board, a motherboard, or the like. At least one integrated circuit device 130 may be attached to a first surface 112 of the electronic substrate 110 with a plurality of interconnects 120. The plurality of interconnects 120 may extend between bond pads 122 formed in or on a first surface 132 (also known as the “active surface”) of the integrated circuit device 130, and substantially mirror-image bond pads 124 in or on the first surface 112 of the electronic substrate 110. The at least one integrated circuit device 130 may further include a second surface 134 (also known as the “back surface”) opposing the first surface 132 and at least one side 136 extending between the first surface 132 and the second surface 134 of the at least one integrated circuit device 130. The least one integrated circuit device 130 may be any appropriate device, including, but not limited to, a microprocessor, a multichip package, a chipset, a graphics device, a wireless device, a memory device, an application specific integrated circuit device, combinations thereof, stacks thereof, or the like. The interconnects 120 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys).

An underfill material 126, such as an epoxy material, may be disposed between the first surface 132 of the integrated circuit device 130 and the first surface 112 of the electronic substrate 110, and surrounding the plurality of interconnects 120. As will be understood to those skilled in the art, the underfill material 126 may be dispensed between the first surface 132 of the integrated circuit device 130 and the first surface 112 of the electronic substrate 110 as a viscous liquid and then hardened with a curing process. The underfill material 126 may also be a molded underfill material. The underfill material 126 may provide structural integrity and may prevent contamination, as will be understood to those skilled in the art.

As further shown in FIG. 1, the electronic substrate 110 may provide electrically conductive routes (illustrated as dashed lines 118) between the integrated circuit device 130 and external components (not shown). As will be understood to those skilled in the art, the bond pads 122 of the integrated circuit device 130 may be in electrical communication with integrated circuitry (not shown) within the integrated circuit device 130.

The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. The conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a careless substrate.

As further shown in FIG, 1, a heat dissipation device 140 may be attached to the electronic substrate 110. The heat dissipation device 140 may include a planar structure 142 having a first surface 144 and an opposing second surface 146, and may have at least one extension 152 projecting from the first surface 144 of the planar structure 142 of the heat dissipation device 140. Such as configuration of the heat dissipation device 140 is referred to in the art as an integrated heat spreader or lid. The heat dissipation device extension(s) 152 may be attached to the first surface 112 of the electronic substrate 110 such that the first surface 144 of the planar structure 142 spans, but does not necessarily directly contact a second surface 134 (e.g. opposing the first surface 132) of the integrated circuit device 130, and a thermal interface material 160 may be disposed between the first surface 144 of the planar structure 142 of the heat dissipation device 140 and the second surface 134 of the integrated circuit device 130. The heat dissipation device extension(s) 152 may be attached to the electronic substrate 110 by any appropriate means, including but not limited to a sealant material 156, such as an epoxy, disposed between an attachment surface 154 of the heat dissipation device extension(s) 152 and the first surface 112 of the electronic substrate 110. In one embodiment, the heat dissipation device extension(s) 152 extend substantially perpendicular to the first surface 144 of the planar structure 142 of the heat dissipation device 140. It is understood that the term substantially perpendicular includes the heat dissipation device extension(s) 152 being plus or minus 5 degrees from 90 degrees.

The heat dissipation device 140 may be formed from any appropriate thermally conductive material, including, but not limited to copper, aluminum, nickel, alloys thereof, and the like. In one embodiment, the heat dissipation device 140 may be formed from a molding or a stamping process, such that the heat dissipation device 140 is a single continuous material. In another embodiment, the planar structure 142 of the heat dissipation device 140 may be formed separately from the extension(s) 152 of heat dissipation device 140 and attached together.

FIG. 2 illustrates the thermal interface material 160 disposed between the first surface 144 of the planar structure 142 of the heat dissipation device 140 and the second surface 134 of the integrated circuit device 130. In one embodiment of the present description, the thermal interface material 160 may comprise a liquid metal 162 and a corrosion resistant filler material 164 (e.g. a plurality of particles) dispersed therein.

The liquid metal 162 may be any appropriate metal or metal alloy that has a low melting point, which forms a eutectic that is liquid at room temperature (e.g. about 22 to 25 degrees Celsius). In one embodiment, the liquid metal may be a gallium or alloys thereof. In a specific embodiment, the liquid metal may be an alloy of gallium, indium, and tin, known as galinstan. In an embodiment, the liquid metal may be between about 62 and 95 percent by weight gallium, between about 4 and 22 percent by weight indium, and between about 1 and 16 percent by weight tin. Liquid metals, such as the liquid metal 162, may be advantageous in the thermal interface material 160 due to its extremely low thermal resistance, and has been used as such. However, the liquid metal 162 alone as the thermal interface material 160 may be susceptible to pump out (as previously discussed) and lacks control over the bond line thickness BLT of the thermal interface material 160, as will be understood to those skilled in the art. The addition of the corrosion resistant filler material 164 may increase viscosity and reduce the risk of thermal interface material 160 pump out. Furthermore, the corrosion resistant filler material 164 may allow for bond line thickness BLT control by allowing the heat dissipation device 140 to bottom out on the largest particles, e.g. having the highest diameter of the corrosion resistant filler material 164, as will be understood to those skilled in the art.

The corrosion resistant filler material 164 may be any appropriate material that is resistant to corrosion from the liquid metal 162. As the thermal interface material 160 must be highly thermally conductive, metals and metals alloys may be contemplated as filler material; however, liquid metals are generally corrosive to metals and alloys. For example, gallium is corrosive to all metals, except tungsten and tantalum. Thus, the term “corrosion resistant” is defined to be resistant to corrosion from the liquid metal 162 into which it is dispersed. It is understood that the degradation process of the corrosion will decrease the thermal performance of the thermal interface material as a function of time and temperature.

In one embodiment of the present description, the corrosion resistant filler material 164 may comprise non-metallic material, including, but not limited to, polymers and ceramics, and/or may comprises metallic fillers that have little or no corrosion with regard to the liquid metal 162 selected. In a further embodiment of the present description, the corrosion resistant filler material 164 may comprise a polymer, including, but not limited to, silicones, polyolefins, polyamides, polytetrafluoroethylene (PTFE), polyimides, and the like. In another embodiment of the present description, the corrosion resistant filler material 164 may comprise ceramic materials, including, but not limited to, boron nitride (BN), aluminum oxide (Al₂O₃), silicon carbide (SiC), silicon oxide (SiO₂), zinc oxide (ZnO), and the like. In still another embodiment of the present description, the corrosion resistant filler material 164 may be a metal or alloy filler that is less susceptible to corrosion, including, but not limited to, amorphous metals and refractory metals, such as tungsten.

The combination of the liquid metal 162 and the corrosion resistant filler material 164 may develop a stable composite thermal interface material 160, as adding the corrosion resistant filler material 164 to the liquid metal 162 may increase the viscosity of the thermal interface material 160, which may reduce the risk of pump out. The increase in viscosity of the thermal interface material 160 may be due to high surface tension of the liquid metal 162 combined with the wetting behavior of the liquid metal 162. to the corrosion resistant filler material 164. After the corrosion resistant filler material 164 is wet by the liquid metal 162, the liquid metal 162 binds the thermal interface material 160 together causing the viscosity to increase. In one embodiment, the thixotropic index of the thermal interface material 160 may be increased allowing for a network of the particles of the corrosion resistant filler material 164 to maintain its shape. This dynamic nature can allow the thermal interface material 160 to move with the integrated circuit package 100 during different warpage states, as will be understood to those skilled in the art.

Furthermore, the combination of the liquid metal 162 and the corrosion resistant filler material 164 may allow for bond line thickness BLT control, as the heat dissipation device 140 may bottom out on the maximum diameter D of the corrosion resistant filler material 164.

As will be understood, the liquid metal 162 and the corrosion resistant filler material 164 may be chosen and/or may be concentrated in any appropriate manner to result in desired properties for the thermal interface material 160. In one embodiment, the liquid metal may be between about 40% and 99.5% by weight of thermal interface material 160 with the remainder being the corrosion resistant filler material 164. Additionally, a combination of various shapes and sizes of corrosion resistant filler material 164 can be used to tune the desired material. For example, the size of the corrosion resistant filler material 164 can be used to tune the desired bond line thickness BLT for the thermal interface material 160 by selecting a maximum particle size, and the viscosity can be tuned by adding smaller particle sized of the thermal interface material 160, which imparts a higher viscosity. Furthermore, thermal conductivity of the thermal interface material 160 may be adjusted by the selection of the material (i.e. ceramic, polymer, etc.) of the corrosion resistant filler material 164, as well as by the selection of the sizes of the particles of the corrosion resistant filler material 164. The shape (e.g. sphere, platelet, aggregates, etc.) of the corrosion resistant filler material 164 can also be used to tune the performance of the thermal interface material 160, where rounder particles show a decreased viscosity, while platelets show higher viscosities. The shape of the corrosion resistant filler material 164 may also impact the thermal performance of the thermal interface material 160, as shapes that can better pack show improved thermal performance, as will be understood to those skilled in the art. Furthermore, the particle size and concentration of the corrosion resistant filler material 164 within the thermal interface material 160 can be modulated to tune the rheology of the thermal interface material 160, so that a suitable application method can be chosen, as will also be understood to those skilled in the art.

As further shown in FIG. 1, the integrated circuit assembly 100 may further include a corrosion barrier layer 148, such as nickel, formed on the first surface 144 of the planar structure 142 of the heat dissipation device 140. As will be understood, the corrosion barrier layer 148 is positioned to prevent corrosion of the heat dissipation device 140 by the liquid metal 162 in the thermal interface material 160. Ordinarily, the materials of the integrated circuit device 130 will not be susceptible to corrosion from the liquid metal 162. of the thermal interface material 160. However, if it is, then a second corrosion barrier layer (not shown) may be placed between the thermal interface material 160 and the integrated circuit device 130.

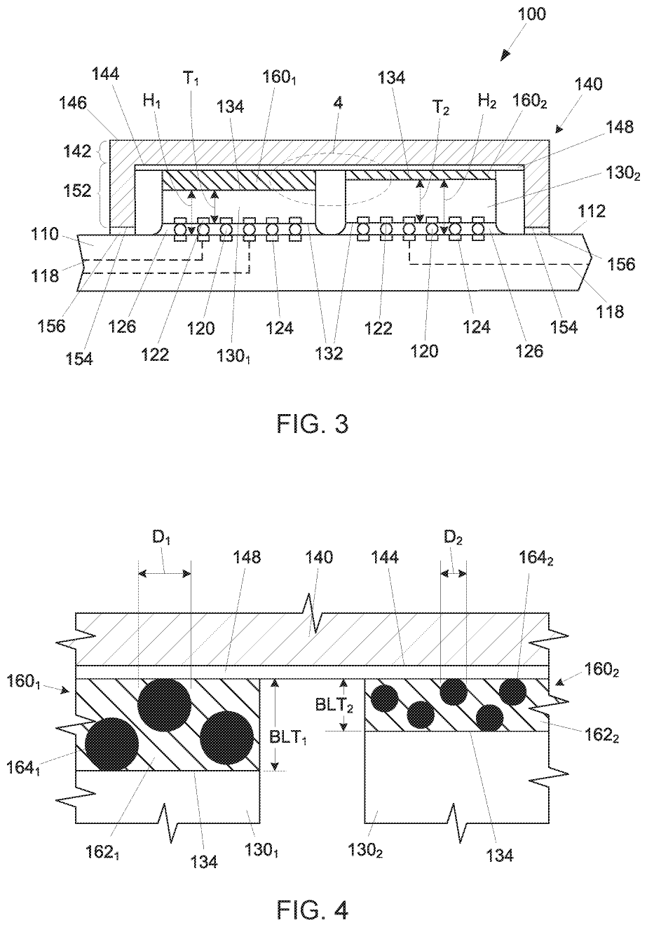

Although the embodiment of FIGS. 1 and 2 illustrate a single integrated circuit device 130, the embodiments of the present description are not so limited. In a further embodiment, as illustrated in FIG. 3, a plurality of integrated circuit devices (e.g. a first integrated circuit device 130₁ and a second integrated circuit device 130₂) may be thermally attached to the heat dissipation device 140, with a first thermal interface material 160₁ between the first integrated circuit device 130₁ and the heat dissipation device 140, and with the second thermal interface material 160₂ between the second integrated circuit device 130₂ and the heat dissipation device 140. In one embodiment, the first thermal interface material 160₁ and the second thermal interface material 160₂ may be the same material. In another embodiment, the first thermal interface material 160₁ and the second thermal interface material 160₂ may be differing materials.

As will be understood, the plurality of integrated circuit devices may have different thicknesses. For example, as the as shown in FIGS. 3 and 4, the first integrated circuit device 130₁ and the second integrated circuit device 130₂ may have differing thicknesses T₁ and T₂ (see FIG. 3), respectively, that is measured from the first surface 132 to the second surface 134 of the first integrated circuit device 130₁ and the second integrated circuit device 130₂, respectively. The differing thickness T₁ and T₂ may result in differing heights H₁ and H₂ between the first integrated circuit device 130₁ and the second integrated circuit device 130₂, respectively, that is measured from the first surface 112 of the electronic substrate 110 to the second surface 134 of each of the first integrated circuit device 130₁ and the second integrated circuit device 1302, respectively, which may result in differing bond line thickness BLT₁ and BLT₂ (see FIG. 4), respectively. Thus, as illustrated in FIG. 4, the corrosion resistant filler material 164₁ of the first thermal interface material 160₁ may have a larger maximum diameter D₁ than the corrosion resistant filler material 164₂ maximum diameter D₂ to compensate for the difference between the height H₁ of the first integrated circuit device 130₁ and the height H₂ of the second integrated circuit device 130₂. In one embodiment, if the bond line thickness BLT₂ of the second integrated circuit device 130, is extremely small, the second thermal interface material 160₂ may have no filler material at all.

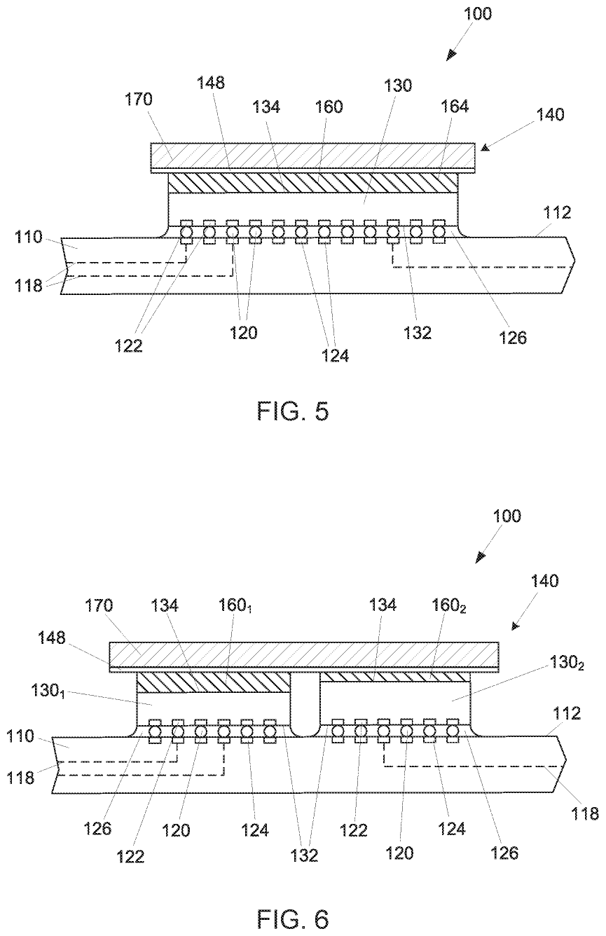

Although the embodiments of FIGS. 1-4 are illustrated with a heat dissipation device 140 as an integrated heat spreader or lid, as previously discussed, the embodiments of the present description are not so limited. As shown in FIG. 5, the heat dissipation device 140 may comprise a heat sink or plate 170. As shown in FIG. 6, the heat sink or plate 170 may be used in an integrated circuit assembly 100 having a plurality of integrated circuit devices (such as shown in FIG. 3).

It is understood that one or more additional heat dissipation devices (not shown), including but not limited to heat pipes, high surface area dissipation structures with a fan (such as a structure having fins or pillars/columns formed in a thermally conductive structure), liquid cooling devices, and the like, may be thermally connected to the heat dissipation device 140 to remove heat therefrom in any of the embodiments of the present description.

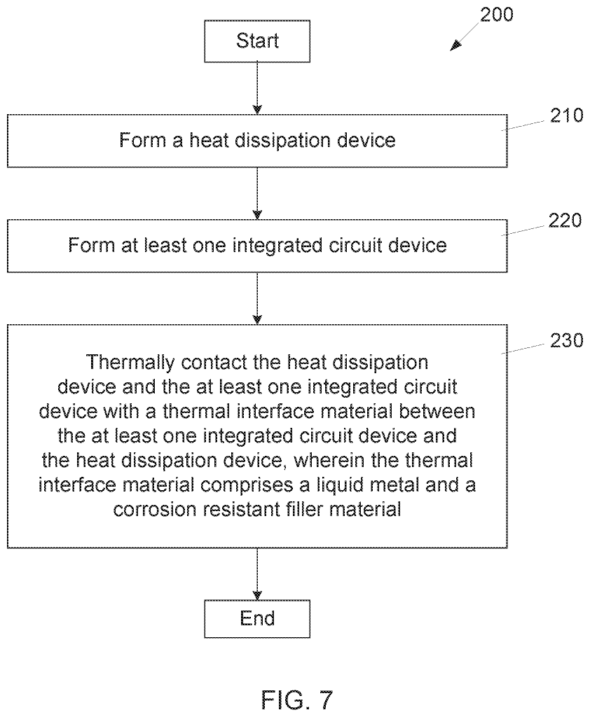

FIG. 7 is a flow chart of a process 200 of fabricating an integrated circuit assembly according to an embodiment of the present description. As set forth in block 210, at least one integrated circuit device may be formed. A heat dissipation device may be formed, as set forth in block 220. As set forth in block 230, the heat dissipation device and at least one integrated circuit device may be brought into thermal contact with a thermal interface material disposed between the heat dissipation device and the at least one integrated circuit device, wherein the thermal interface material comprises a liquid metal and a corrosion resistant tiller material.

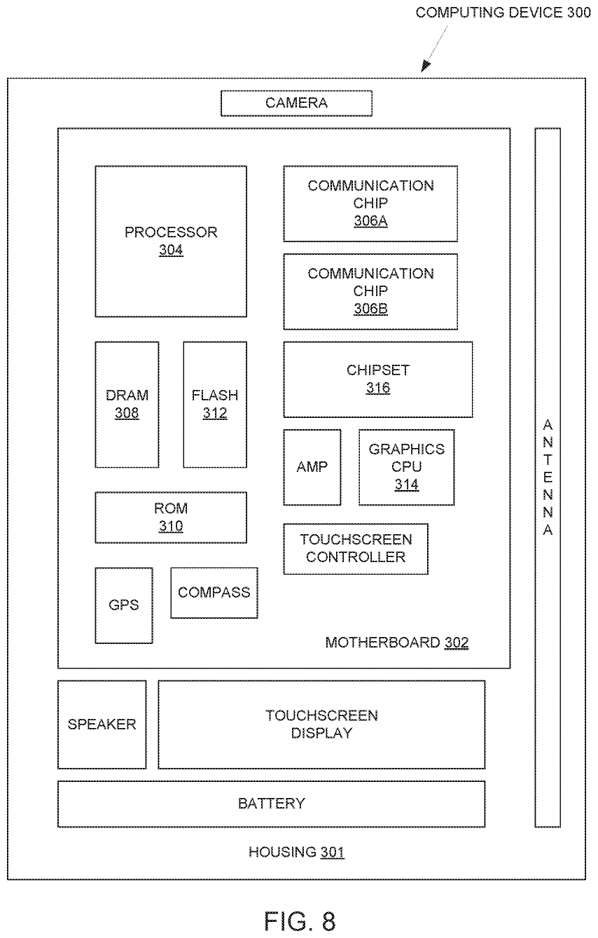

FIG. 8 illustrates an electronic system or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip or device may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include at least one integrated circuit device, a heat dissipation device thermally contacting the at least one integrated circuit device, and a thermal interface material between the at least one integrated circuit device and the heat dissipation device, wherein the thermal interface material comprises a metal and a corrosion-resistant filler material.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-8. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an integrated circuit assembly, comprising at least one integrated circuit device; a heat dissipation device thermally contacting the at least one integrated circuit device; and a thermal interface material between the at least one integrated circuit device and the heat dissipation device, wherein the thermal interface material comprises a liquid metal and a corrosion resistant filler material.

In Example 2, the subject matter of Example 1 can optionally include the liquid metal comprising an alloy of gallium, indium, and tin.

In Example 3, the subject matter of Example 2 can optionally include the liquid metal comprising between about 62 and 95 percent by weight gallium, between about 4 and 22 percent by weight indium, and between about 1 and 16 percent by weight tin,

In Example 4, the subject matter of any of Examples 1 to 3 can optionally include the corrosion resist material comprising a polymer.

In Example 5, the subject matter of any of Examples 1 to 3 can optionally include the corrosion resist material comprising a ceramic material.

In Example 6, the subject matter of any of Examples 1 to 3 can optionally include the corrosion resist material comprising an amorphous metal.

In Example 7, the subject matter of any of Examples 1 to 3 can optionally include the corrosion resist material comprising a refractory metal.

In Example 8, the subject matter of any of Examples 1 to 7 can optionally include a corrosion resist layer formed between the heat dissipation device and the thermal interface material.

In Example 9, the subject matter of any of Examples 1 to 8 can optionally include an electronic substrate, wherein the at least one integrated circuit device is electrically attached to the electronic substrate.

In Example 10, the subject matter of Example 9 can optionally include the heat dissipation device being attached to the electronic substrate.

Example 11 is an electronic system, comprising a board and an integrated circuit assembly electrically attached to the board, wherein the integrated circuit assembly comprises an integrated circuit assembly, comprising at least one integrated circuit device, a heat dissipation device thermally contacting the at least one integrated circuit device, and a thermal interface material between the at least one integrated circuit device and the heat dissipation device, wherein the thermal interface material comprises a liquid metal and a corrosion resistant filler material.

In Example 12, the subject matter of Example 11 can optionally include the liquid metal comprising an alloy of gallium, indium, and tin.

In Example 13, the subject matter of Example 12 can optionally include the liquid metal comprising between about 62 and 95 percent by weight gallium, between about 4 and 22 percent by weight indium, and between about 1 and 16 percent by weight tin.

In Example 14, the subject matter of any of Examples 11 to 13 can optionally include the corrosion resist material comprising a polymer.

In Example 15, the subject matter of any of Examples 11 to 13 can optionally include the corrosion resist material comprising a ceramic material.

In Example 16, the subject matter of any of Examples 11 to 13 can optionally include the corrosion resist material comprising an amorphous metal.

In Example 17, the subject matter of any of Examples 11 to 13 can optionally include the corrosion resist material comprising a refractory metal.

In Example 18, the subject matter of any of Examples 11 to 17 can optionally include a corrosion resist layer formed between the heat dissipation device and the thermal interface material.

In Example 19, the subject matter of any of Examples 11 to 18 can optionally include an electronic substrate, wherein the at least one integrated circuit device is electrically attached to the electronic substrate.

In Example 20, the subject matter of Example 9 can optionally include the heat dissipation device being attached to the electronic substrate.

Example 21 is a method of fabricating an integrated circuit assembly comprising forming a heat dissipation device, forming at least one integrated circuit device, and thermally contacting the heat dissipation device and the at least one integrated circuit device with a thermal interface material between the at least one integrated circuit device and the heat dissipation device, wherein the thermal interface material comprises a liquid metal and a corrosion resistant filler material.

In Example 22, the subject matter of Example 21 can optionally include the liquid metal comprising an alloy of gallium, indium, and tin.

In Example 23, the subject matter of Example 22 can optionally include the liquid metal comprising between about 62 and 95 percent by weight gallium, between about 4 and 22 percent by weight indium, and between about 1 and 16 percent by weight tin.

In Example 24, the subject matter of any of Examples 21 to 23 can optionally include forming the corrosion resist material from a polymer.

In Example 25, the subject matter of any of Examples 21 to 23 can optionally include forming the corrosion resist material from a ceramic material.

In Example 26, the subject matter of any of Examples 21 to 23 can optionally include forming the corrosion resist material comprising an amorphous metal.

In Example 27, the subject matter of any of Examples 21 to 23 can optionally include forming the corrosion resist material comprising a refractory metal.

In Example 28, the subject matter of any of Examples 21 to 27 can optionally include forming a corrosion resist layer between the heat dissipation device and the thermal interface material.

In Example 29, the subject matter of any of Examples 21 to 28 can optionally include forming an electronic substrate and electrically attaching the at least one integrated circuit device to the electronic substrate.

In Example 30, the subject matter of Example 29 can optionally include attaching the heat dissipation device to the electronic substrate.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An integrated circuit assembly, comprising:
at least one integrated circuit device;
a heat dissipation device thermally contacting the at least one integrated circuit device; and
a thermal interface material between the at least one integrated circuit device and the heat dissipation device, wherein the thermal interface material comprises a liquid metal and a corrosion resistant filler material.

2. The integrated circuit assembly of claim 1, wherein the liquid metal comprises an alloy of gallium, indium, and tin.

3. The integrated circuit assembly of claim 2, wherein the liquid metal comprises between about 62 and 95 percent by weight gallium, between about 4 and 22 percent by weight indium, and between about 1 and 16 percent by weight tin.

4. The integrated circuit assembly of claim 1, wherein the corrosion resist material comprises a polymer.

5. The integrated circuit assembly of claim 1, wherein the corrosion resist material comprises a ceramic material.

6. The integrated circuit assembly of claim 1, wherein the corrosion resist material comprises an amorphous metal.

7. The integrated circuit assembly of claim 1, wherein the corrosion resist material comprises a refractory metal.

8. The integrated circuit assembly of claim 1, further comprising a corrosion barrier layer formed between the heat dissipation device and the thermal interface material.

9. The integrated circuit assembly of claim 1, further comprising an electronic substrate, wherein the at least one integrated circuit device is electrically attached to the electronic substrate.

10. The integrated circuit assembly of claim 9, wherein the heat dissipation device is attached to the electronic substrate.

11. An electronic system, comprising:
a board; and
an integrated circuit assembly electrically attached to the board, wherein the integrated circuit assembly comprises:
at least one integrated circuit device;
a heat dissipation device thermally contacting the at least one integrated circuit device; and
a thermal interface material between the at least one integrated circuit device and the heat dissipation device, wherein the thermal interface material comprises a liquid metal and a corrosion resistant filler material.

12. The electronic system of claim 11, wherein the liquid metal comprises an alloy of gallium, indium, and tin.

13. The electronic system of claim 12, wherein the liquid metal comprises between about 62 and 95 percent by weight gallium, between about 4 and 22 percent by weight indium, and between about 1 and 16 percent by weight tin.

14. The electronic system of claim 11, wherein the corrosion resist material comprises a polymer.

15. The electronic system of claim 11, wherein the corrosion resist material comprises a ceramic material.

16. The electronic system of claim 11, wherein the corrosion resist material comprises an amorphous metal.

17. The electronic system of claim 11, wherein the corrosion resist material co refractory metal.

18. The electronic system of claim 11, further comprising a corrosion barrier layer formed between the heat dissipation device and the thermal interface material.

19. The electronic system of claim 11, further comprising an electronic substrate, wherein the at least one integrated circuit device is electrically attached to the electronic substrate.

20. The electronic system of claim 19, wherein the heat dissipation device is attached to the electronic substrate.

21. A method of fabricating an integrated circuit assembly, comprising:
forming a heat dissipation device;
forming at least one integrated circuit device; and
thermally contacting the heat dissipation device and the at least one integrated circuit device with a thermal interface material between the at least one integrated circuit device and the heat dissipation device, wherein the thermal interface material comprises a liquid metal and a corrosion resistant filler material.

22. The method of claim 21, wherein the liquid metal comprises an alloy of gallium, indium, and tin.

23. The method of claim 21, wherein the corrosion resist material is selected from the group consisting of a polymer, a ceramic material, an amorphous metal, and a refractory metal.

24. The method of claim 21, further comprising forming a corrosion barrier layer between the heat dissipation device and the thermal interface material.

25. The method of claim 21, further comprising forming an electronic substrate and electrically attaching the at least one integrated circuit device to the electronic substrate.
